(19) United States
(12) Patent Application Publication
(10) Pub. No.: US 2005/0051099 A1
(43) Pub. Date: Mar. 10, 2005

(54) Susceptor provided with indentations and an epitaxial reactor which uses the same

(76) Inventors: Franco Preti, Milano (IT); Vincenzo Ogliari, Capegnanica (IT)

Correspondence Address: KATTEN MUCHIN ZAVIS ROSENMAN, 575 MADISON AVENUE, NEW YORK, NY, 10022-2585, US

(21) Appl. No.: 10/916,780

(22) Filed: Aug. 12, 2004

Related U.S. Application Data
(63) Continuation of application No. PCT/EP03/01305, filed on Feb. 10, 2003.

(30) Foreign Application Priority Data
Feb. 15, 2002 (IT) MI2002A000306

(51) Int. Cl. C23C 16/00

(52) U.S. Cl. 118/728

(57) ABSTRACT

The disc susceptor (1) for epitaxial growth reactors is of the type adapted to be heated by induction and is provided with an upper side (11) and with a lower side (12); at least one recess (2) adapted to house at least one corresponding substrate (3) to be subjected to epitaxial growth is formed in the upper side (11); indentations (4) such as to reduce locally the thickness of the susceptor (1) are provided on the lower side (12) in regions corresponding to the peripheral regions of the recess (2).

The present invention relates to a susceptor for epitaxial growth reactors according to the preamble of claim 1 and to an epitaxial reactor which uses the same.

In the field of epitaxial reactors for the microelectronics industry, the term “susceptor” refers to the support which houses one or more substrates during the epitaxial growth process; this support is often heated by induction, by making use of its susceptance, and the substrates are heated most of all by thermal contact with the susceptor; the support generally retains the name of “susceptor” even in those reactors in which the heating takes place by other methods, for example, by means of lamps.

The present invention is directed towards susceptors of the type adapted to be heated by induction.

It is known that, during the epitaxial growth process, the various points of the susceptor may adopt temperatures which differ (possibly greatly, for example, by tens of degrees) in relation to the shape and cross-section of the susceptor; it is therefore necessary to take account of this at the susceptor-design stage.

Defects of various types (which, naturally, are to be avoided) may arise in the substrates grown; amongst these defects there are the so-called “slip lines” which are well-known to persons skilled in the art.

The “slip lines” phenomenon is complex and, up to now, has not been fully explained; the non-uniformity of the temperature of the substrate surface on which the growth takes place during the growth process is considered to be amongst their causes; it appears from recent studies that the weight of the layers of material grown on the substrate also has an effect.

Susceptors for epitaxial reactors can be divided into two large categories: those in which the substrates are in a substantially horizontal position during the epitaxial growth process (disc susceptors) and those in which the substrates are in a substantially vertical position, often inclined by a few degrees to the vertical, during the epitaxial growth process (pyramid susceptors).

Both categories share the objective of producing grown substrates that are free of both microscopic and macroscopic defects (such as, for example, slip lines) and hence, amongst other things, to achieve a uniform temperature on the surface of the substrate on which the growth takes place.

The two categories have similarities but also substantial differences: a first difference is, for example, that in pyramid reactors the temperature of the surface of the substrate on which the growth takes place is affected by convection movements of the gas that is inside the reaction chamber, which occur between the wall of the chamber and the susceptor; a second difference is, for example, that the weight of the layers of material acts on the substrate in a perpendicular direction in disc susceptors and in a parallel direction in pyramid reactors; naturally, there is a clear geometrical difference. These differences, which may even seem marginal, have an effect on the substrates grown which cannot be ignored since the geometrical shapes of the electronic devices produced with these substrates are very small and are continually being reduced, and because requirements relating to material quality are consequently very high greater and are continually being increased.

Various solutions and various measures have already been proposed in the past both for reactors with disc susceptors (see, for example European patent 730679) and for reactors with pyramid susceptors (see, for example, European patent 293021); the various solutions and the various measures have been found to be more or less effective and more or less easy to implement and to put into effect, according to circumstances.

The present invention is directed towards disc susceptors.

It has been found from careful experimental tests that, even if the temperature of a disc susceptor heated by induction is very uniform throughout its mass, the temperature of that surface of the substrate housed in a recess of the susceptor on which the growth takes place is slightly lower (by a few degrees or even less) in the peripheral regions, in comparison with the central regions. As well as causing a slight difference in the thickness of the layer grown (which is generally substantially negligible) this temperature difference gives rise to slip lines.

To be precise, it should also be mentioned that, if the heating of the substrate takes place exclusively by contact with the susceptor, there is a slight temperature differential in the vertical direction.

The lower temperature of the peripheral regions of the substrate may perhaps be explained by the fact that the vertical edge of the substrate is not generally in contact with the vertical edge of the recess of the susceptor; the difference between the radius of the substrate and the radius of the recess is about 1 mm and serves to enable the substrate to be inserted in the recess without risk of harmful knocks; the vertical edge of the substrate thus receives a heat flow by conduction from the neighbouring regions of the substrate, a heat flow by contact with the atmosphere of the reaction chamber, and a heat flow by radiation coming from the neighbouring surface of the recess.

The object of the present invention is therefore to provide a disc susceptor of the type adapted to be heated by induction, which overcomes the disadvantages of the prior art.

This object is achieved by means of the susceptor having the features set forth in independent claim 1. Further advantageous aspects of the present invention are set forth in the dependent claims.

The concept upon which the invention is based is that of providing the means for heating the susceptor and the susceptor itself in a manner such as to achieve a uniform temperature in its recess or recesses and then to apply small geometrical modifications to the susceptor in a manner such that the temperature of the recess in regions corresponding to the peripheral regions of the substrate is appropriately slightly higher; these small geometrical modifications consist of a small local reduction in the cross-section of the susceptor, which leads to an increase in the density of current induced and hence in the heat generated by the Joule effect.

A further aspect of the present invention also relates to an epitaxial reactor which has the features set forth in independent claim 9, and which uses such a susceptor.

The present invention will become clearer from the following description, considered together with the appended drawings which relate to embodiments of the present invention and in which:

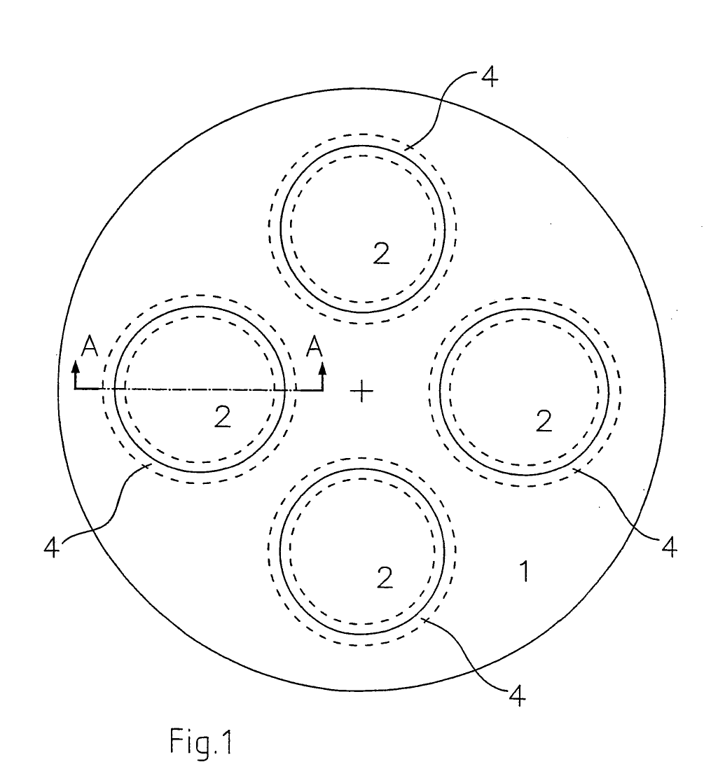

FIG. 1 is a view showing a first susceptor according to the present invention, from above,

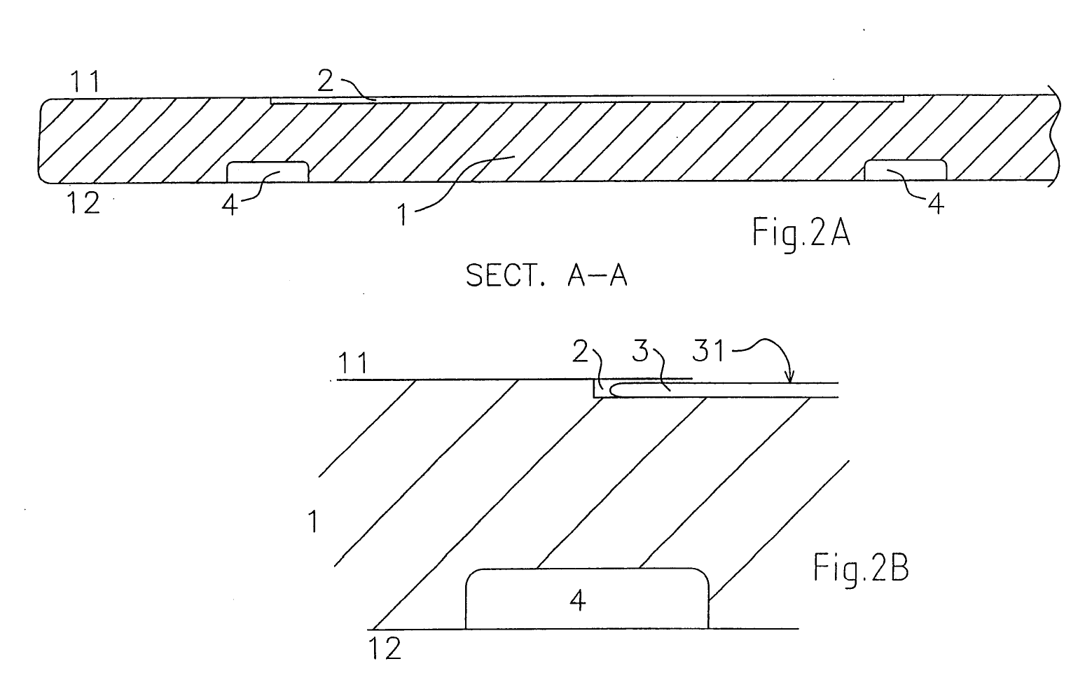

FIG. 2A shows a vertical section through a portion of the susceptor of FIG. 1,

FIG. 2B shows an enlarged detail of the view of FIG. 2A,

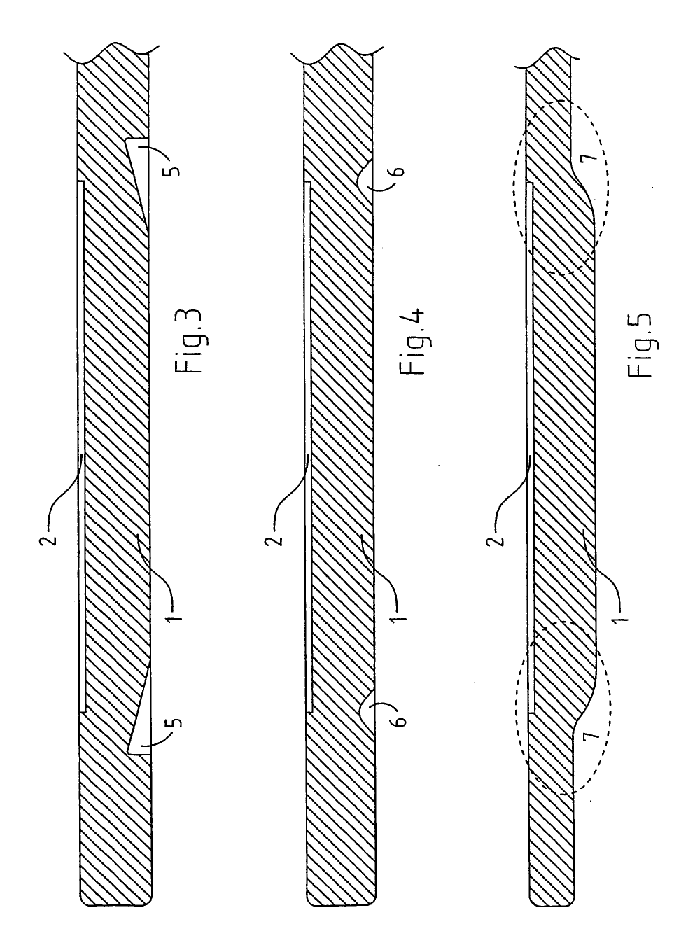

FIG. 3 shows a vertical section through a portion of a second susceptor according to the present invention,

FIG. 4 shows a vertical section through a portion of a third susceptor according to the present invention, and

FIG. 5 shows a vertical section through a portion of a fourth susceptor according to the present invention.

The disc susceptor for epitaxial growth reactors according to the present invention is of the type adapted to be heated by induction and has an upper side and a lower side; at least one recess adapted to house at least one corresponding substrate to be subjected to epitaxial growth is formed in the upper side; indentations such as to reduce locally the thickness of the susceptor are provided in the lower side, in regions corresponding to the peripheral regions of the recess.

During the reaction stage, this localized reduction in thickness results in a higher temperature of the susceptor in the peripheral regions of the recess; this higher temperature of the peripheral regions of the recess will result in a greater heat flow towards the peripheral regions of the substrate housed in the recess, with a beneficial effect on the uniformity of the temperature of the growth surface of the substrate and hence, amongst other things, on the “slip lines” phenomenon.

These indentations are preferably shaped and distributed in a manner such as to compensate for the temperature differences of the growth surface of the substrate during the reaction stage.

The best results are obtained when all of the indentations are identical and distributed uniformly in a region corresponding to the entire perimeter of the recess.

It is particularly convenient and effective if the indentations constitute a single groove corresponding to the entire perimeter of the recess.

According to the specific embodiment, the cross-section of this groove may have different shapes, that is: substantially rectangular, substantially triangular, substantially semicircular, etc.; the temperature profile of the surface of the recess in the peripheral regions depends on the shape. In the central regions, the thickness of the susceptor is preferably uniform so as to give rise to a uniform temperature in the central regions of the substrate.

The shape, the dimensions, and the positioning of the groove relative to the recess must be selected on the basis of the final result desired (uniformity of temperature); an experimental stage is therefore essential.

If the vertical section of the groove is selected in a manner such that the reduction in thickness of the susceptor increases gradually towards the peripheral regions of the recess, the temperature of the surface of the recess will increase towards its edge; since the substrate housed in a recess has a heat loss which increases gradually towards its edge (which, amongst other things, is not in contact with the edge of the recess), this selection may permit improved compensation; in this case, however, it is necessary to take into account that the exchange of heat between the vertical edge of the substrate and the vertical edge of the recess does not generally take place by thermal contact.

Finally, in implementing the present invention, it is necessary to take into account that the recess itself constitutes a small indentation (on the upper side of the susceptor) which will lead to a small reduction in the thickness of the susceptor in regions corresponding to the central regions of the recess; for shallow recesses and for very thick susceptors, this contribution can be ignored.

The present invention is particularly useful in susceptors which have a plurality of recesses. In fact, without the use of the present invention, for these susceptors, the localized increase in temperature in the regions of the recess edges would involve a complex, critical and expensive arrangement of the susceptor-heating means; moreover, if it were desired to use the susceptor in a reactor with susceptor rotation, a localized increase would be impossible without the use of the present invention.

Some practical embodiments of the present invention will be described below.

The susceptor 1 of FIG. 1 according to the present invention is a disc susceptor and has a substantially circular shape.

On the upper side 11 it has four substantially circular recesses 2 adapted to house substrates, generally made of semiconductor material, on which epitaxial growth is to be performed.

The edges of four indentations 4 corresponding to the four recesses 2 are indicated by broken lines; the indentations 4 are present on the opposite side to that in which the recesses 2 are present, that is, on the lower side 12; in the embodiment of FIG. 1, these indentations 4 take the form substantially of circular rings, are concentric with the corresponding recesses 2, and are symmetrical with respect to the edges of the recesses 2.

The diameter of the susceptor 1 may be, for example, 600 mm and the diameter of the recesses 2 may be, for example, 150 mm.

A portion of the susceptor 1 is visible in the section A-A of FIG. 1; the edge of the susceptor has rounded corners and the faces are substantially parallel with one another; the thickness of the susceptor may be, for example, 15 mm; the recess 2 formed in the susceptor 1 on its upper side 11 has a substantially flat base, parallel to the faces of the susceptor and has a depth which is shallow in comparison with that of the susceptor 1 and which may be, for example, from 0.5 mm to 1 mm; this also relates to the thickness of the possible substrates to be housed in the recess 2; the indentations 4 formed in the susceptor 1 on the lower side 12 may have a depth and a width which are variable in relation to the desired local overheating effect; however, the depth is quite great and may be, for example, from 1 mm to 5 mm; the width may be, for example, from 5 mm to 25 mm.

The indentations 4 of FIG. 1 and FIG. 2 constitute grooves disposed in regions corresponding to the perimeters of the corresponding recesses 2; the grooves of FIG. 2 have a substantially rectangular cross-section (the inner corners of the groove are in fact rounded); in the embodiment of FIG. 1 and FIG. 2, the vertical axis of symmetry of the rectangle corresponds substantially to the edge of the recess 2.

The detail of FIG. 2B also shows, inside the recess 2, a substrate 3 housed therein; the surface 31 of the substrate 3 on which epitaxial growth takes place during the reaction faces upwards and is not in contact with the recess 2 (the thickness of the material grown does not generally exceed 0.1 mm); the surface of the substrate 3 on which growth does not take place faces downwards and is in contact with the base of the recess 2 so as to establish a thermal contact between the susceptor 1 and the substrate 3.

FIG. 3, FIG. 4 and FIG. 5 show respective vertical sections through portions of three different, multi-recess susceptors according to the present invention.

The susceptors of FIG. 3 and of FIG. 4 have indentations which constitute grooves 5 and 6 of substantially triangular shape.

The vertical section through the groove 5 of FIG. 3 is such that the reduction in thickness of the susceptor 1 increases gradually towards the peripheral regions of the recess 2.

The susceptor of FIG. 5 has identical indentations 7 distributed uniformly in a region corresponding to the entire perimeter of the recess 2; these constitute a reduced-thickness region of the susceptor with the shape substantially of a circular ring, the reduction in thickness of the susceptor 1 increases gradually towards the peripheral regions of the recess).

The susceptor according to the present invention can usefully be inserted in an epitaxial growth reactor provided with heating means; at least a portion of the heating means will be suitable for producing induced currents in the susceptor.

1. A disc susceptor (1) for epitaxial growth reactors, of the type adapted to be being heated by induction, provided with an upper side (11) and a lower side (12), wherein at least one recess (2) adapted to house at least one corresponding substrate (3) to be subjected to epitaxial growth is formed in the upper side (11), characterized in that indentations (4, 5, 6, 7) such as to reduce locally the thickness of the susceptor (1) are provided in the lower side (12), in regions corresponding to the peripheral regions of the at least one recess (2).

2. A susceptor according to claim 1 in which the indentations (4, 5, 6, 7) are shaped and distributed in a manner such as to compensate for differences in temperature of the growth surface (31) of the at least one substrate (3) during the reaction stage.

3. A susceptor according to claim 1 in which the indentations (4, 5, 6, 7,) are identical and are distributed uniformly in a region corresponding to the entire perimeter of the at least one recess (2).

4. A susceptor according to claim 3 in which the indentations (4, 5, 6, 7) constitute a single groove corresponding to the entire perimeter of the at least one recess (2).

5. A susceptor according to claim 4, in which the vertical section of the groove (4) is substantially rectangular.

6. A susceptor according to claim 4 in which the vertical section of the groove (5, 6) is substantially triangular.

7. A susceptor according to claim 1 in which the vertical section of the groove (5, 7) is such that the reduction in thickness of the susceptor increases gradually towards the peripheral regions of the at least one recess.

8. A susceptor according to claim 1 in which a plurality of recesses (2), adapted to house a corresponding plurality of substrates (3) to be subjected to epitaxial growth, is formed in the upper side (11).

9. A reactor for epitaxial growth on substrates, characterized in that it comprises at least one susceptor (1) according to claim 1 and heating means suitable for producing induced currents in the susceptor.

10. A reactor for epitaxial growth of substrates comprising:
a disc susceptor to be heated by induction, provided with an upper side and a lower side
at least one recess on the upper side of the disc susceptor for housing a corresponding substrate for epitaxial growth;
indentations on the lower side of the disc susceptor for reducing locally its thickness in connection with the peripheral region of said at least one recess;
inductions heating means for inducing currents in the disc suspector;
whereby higher temperatures of the susceptor in the peripheral regions of said at least one recess are obtained because of the reduced thickness due to indentations.
